(19) United States
(12) Patent Application Publication
(10) Pub. No.: US 2006/0254512 A1
(43) Pub. Date: Nov. 16, 2006

(54) Apparatus for attachment of semiconductor hardware

(75) Inventor: Steven T. Fink, Mesa, AZ (US)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Tokyo Electron Limited, Tokyo (JP)

(21) Appl. No.: 10/546,978

(22) PCT Filed: Feb. 26, 2004
(86) PCT No.: PCT/US04/03361

§ 371 Date: May 31, 2006

Related U.S. Application Data
(60) Provisional application No. 60/450,351, filed on Feb. 28, 2003.

(51) Int. Cl. C23C 16/00

(52) U.S. Cl. 118/715

(57) ABSTRACT

A plasma processing method and system including an apparatus and method for securing semiconductor hardware without the use of exposed threaded hardware. Consistent mechanical and electrical contact between parts in the assembled condition can also be achieved.

### CROSS REFERENCE TO RELATED APPLICATIONS

This application claims priority to and is related to U.S. Provisional Application Ser. No. 60/450,351, filed on Feb. 28, 2003. The contents of which are incorporated herein by reference.

### BACKGROUND OF THE INVENTION

1. Field of the Invention

The present invention is directed to an apparatus and method for securing semiconductor hardware, and more specifically to securing such hardware without the use of exposed threaded hardware.

2. Discussion of the Background

During the manufacturing and production of semiconductors, the use of plasma process chambers is sometimes necessary. Silicon wafers, providing a starting material for semiconductors, are loaded into chambers and exposed in various steps to process plasma.

The plasma condition in process chambers can vary substantially, and many things can contribute to and subtract from the plasma generated. Process chambers contain multiple parts that affect plasma chemistry. Some of these parts are attached with common threaded fasteners. These fasteners, many times, can become a problem when generating particular plasmas because they may require hardware shielding after installation.

A need exists for an attachment apparatus that minimizes the hardware necessary to assemble internal components of a plasma-processing chamber. Removal of parts secured with hardware, especially threaded hardware, is time consuming, requires hand or power tools and tends to create particles as the hardware is removed and subsequently replaced. Additional hardware increases time for procurement, inspection, cleaning, assembly and control.

When installing parts using threaded hardware, consistent assembly is difficult to accomplish. To obtain consistent interface between parts, secured by threaded fasteners, the fasteners must be secured to specific torque requirements. This also requires additional tools. A need exists to consistently assemble internal plasma processing piece parts without special tools, process and inspections.

The presence of metallic particles in a plasma process can, at times, be a significant problem. Many times, metallic hardware is shielded from the plasma to solve this problem. These shielding parts add additional parts required in the plasma tool. A need therefore exists for a way to attach parts in a plasma chamber so that shielding parts are not required or a shielding function is accomplished without adding extra parts.

### SUMMARY OF THE INVENTION

These and other problems are addressed by the present invention which provides an apparatus and method for attaching replaceable parts within a process chamber such that the need to clean the chamber is reduced.

A first embodiment of the invention includes an external bayonet type interface between a first processing component and a second processing component.

A second embodiment of the invention includes an internal bayonet type interface between a first processing component and a second processing component.

A third embodiment of the invention utilizes two or more threaded fasteners used to mate a first processing component to a second processing component.

A fourth embodiment of the invention uses two or more support pins, with various shaped support pin retainer assemblies that allow insertion and removal by hand.

### BRIEF DESCRIPTION OF THE DRAWINGS

The above-noted and other aspects of the present invention will become more apparent from a detailed description of preferred embodiments when read in conjunction with the drawings, wherein:

FIG. 1 is a cross-sectional view showing main components of a capacitively coupled plasma generating tool fastening system showing an external bayonet type interface between a ceramic insulator and a shield ring;

FIG. 2 is a cross-sectional view of the external bayonet interface between a shield ring and a ceramic insulator;

FIG. 3A is a cross-sectional view of a support pin in external communication with a support pin groove of a ceramic insulator;

FIG. 3B is an alternate cross-sectional view of a support pin in communication with a support pin groove of a ceramic insulator;

FIG. 4 is a cross-sectional view showing main components of a capacitively coupled plasma generating tool fastening system showing an internal bayonet type interface between a ceramic insulator and an inject plate;

FIG. 5 is a cross-sectional view of the internal bayonet interface between the ceramic insulator and the inject plate;

FIG. 6A is a cross-sectional view of a support pin in internal communication with a support pin groove of a ceramic insulator;

FIG. 6B is an alternate cross-sectional view of a support pin in communication with a support pin groove of a ceramic insulator;

FIG. 7 is a cross-sectional view of the main components of a capacitively coupled plasma generating tool fastening system showing a UEL plate—lower in communication with an inject plate through the use of a hardware attachment;

FIG. 8 is a cut-away view of the fastening system of FIG. 7, a ceramic insulator, and an inject plate having a retaining groove and a groove counterbore;

FIG. 9 is a cross-sectional view of the fastening system of FIG. 7;

FIG. 10 is a cross-sectional view of a plasma processing chamber utilizing a support pin retainer assembly which allows removal of support pins by hand;

FIG. 11 is a cut-away cross-sectional view of the retainer assembly of FIG. 10; and

FIG. 12 is a cut-away plan view of the retainer assembly of FIG. 10.

### DETAILED DESCRIPTION OF THE PREFERRED EMBODIMENTS

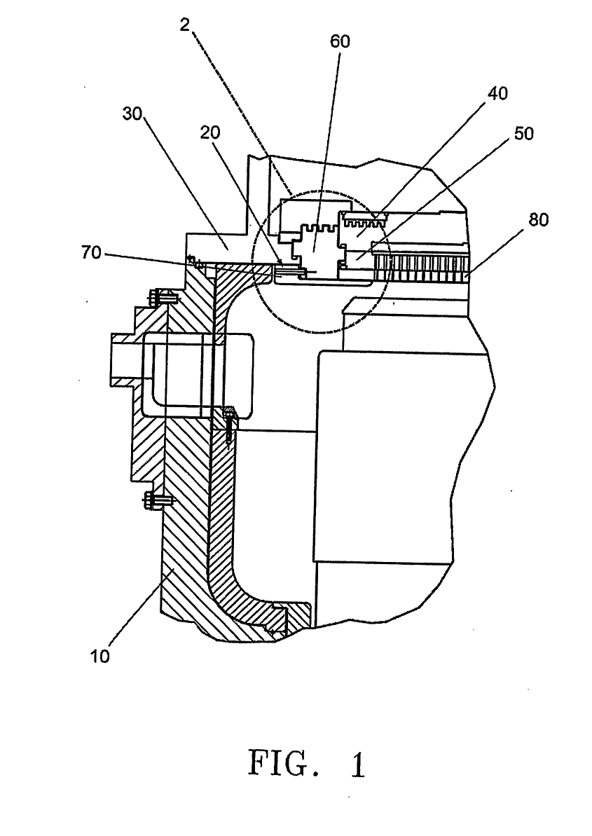

FIGS. 1, 2, 3A and 3B show an embodiment of a plasma process chamber 10 utilizing an external bayonet fastening apparatus 20 for coupling a first processing component with a second processing component. The plasma process chamber is typically configured such that an upper housing 30 is electrically insulated from an upper plate 40 of an upper electrode (UEL) and a lower plate 50 of the upper electrode by a ceramic insulator 60. A shield ring 70 (e.g., a quartz shield ring) is positioned below the ceramic insulator 60.

The shield ring 70 is positioned inside the process chamber 10 underneath the upper housing 30, ceramic insulator 60, and an inject plate 80. The shield ring 70 has two or more support pins 90 embedded therein and protruding toward the center of the process chamber 10. The support pins may or may not be fabricated from the same material as the shield ring 70.

A support pin groove 100 in the ceramic insulator 60 is associated with each support pin 90 in the shield ring 70. Each support pin groove 100 has a support pin receiving feature 110 which allows reception of a support pin 90. Once support pins 90 are mounted in the support pin receiving feature 110, rotation of the shield ring 70 is possible. Rotation of the shield ring 70 is accomplished until the support pins 90 contact a stop feature 120 in the support pin groove 100. In order to access the shield ring 70 for installation, replacement, etc., the upper housing 30 is lifted away from the process chamber 10. For example, the upper housing 30 can be coupled to the process chamber 10 via a hinge assembly (not shown), and the upper housing can be lifted away, as if it were a lid, to expose the shield ring 70 and the electrode plate 80. Thereafter, the shield ring 70 can be removed and replaced by simply rotating and withdrawing the support pin 90 from the support pin receiving feature 110.

During rotation of the shield ring 70, the support pins 90 travel along a support pin groove recess 130. The support pin groove recess 130 has an upper surface 140 and a lower surface 150.

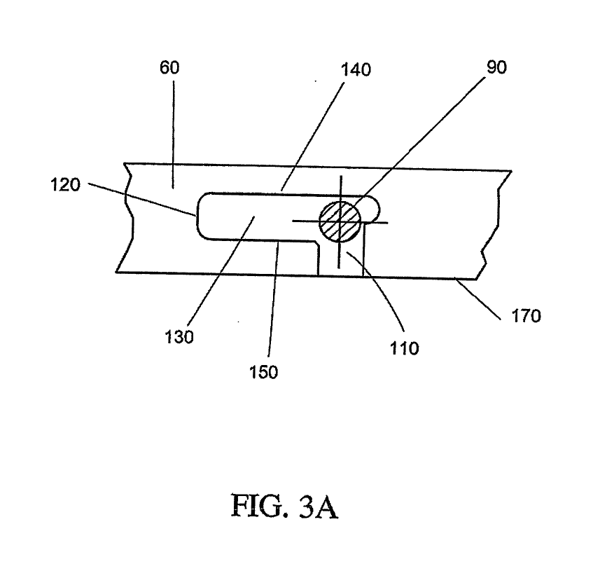

FIG. 3A depicts a possible design of support pin groove 100. The upper surface 140 and the lower surface 150 of the support pin groove recess 130 are approximately parallel to a bottom surface 170 of the ceramic insulator 60.

As shown in FIG. 3B, a further possible design of support pin groove 100 is shown. The upper surface 140 and the lower surface 150 of the support pin groove recess 130 are set at an angle alpha to the bottom surface 170 of the ceramic insulator 60 which is not zero degrees. This angle can allow an axial force between the shield ring 70 and the ceramic insulator 60 when the shield ring 70 is rotated with respect to the ceramic insulator.

Other embodiments of groove design are possible. Any types of groove shapes that allow a pin to move along during rotation are possible and are similar to the embodiments shown in FIGS. 3A and 3B.

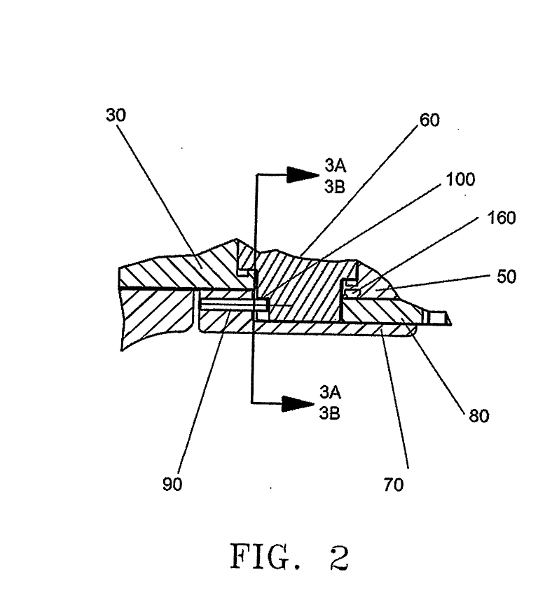

An electrical contact device 160 (see FIG. 2) can be positioned between the inject plate 80 and the lower UEL plate 50. During rotation of the shield ring 70 the electrical contact device 160 is slightly deformed as it is captivated in its mounting groove. This deformation ensures consistent contact between the inject plate 80 and the lower UEL plate 50.

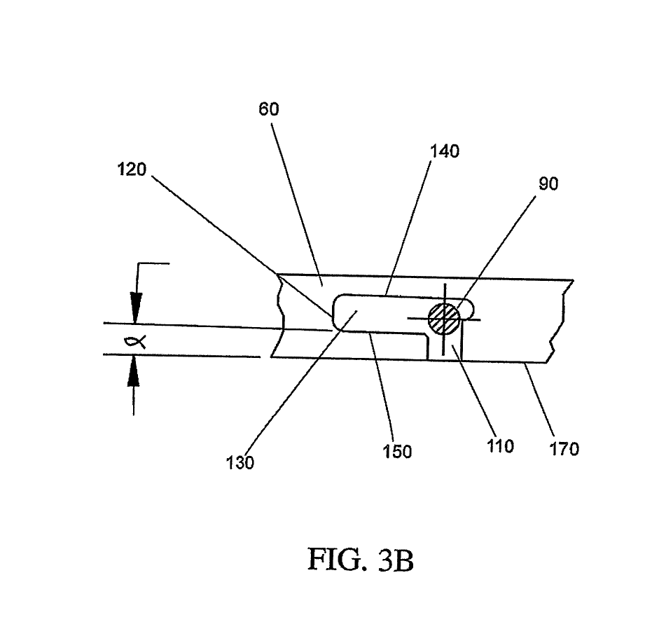

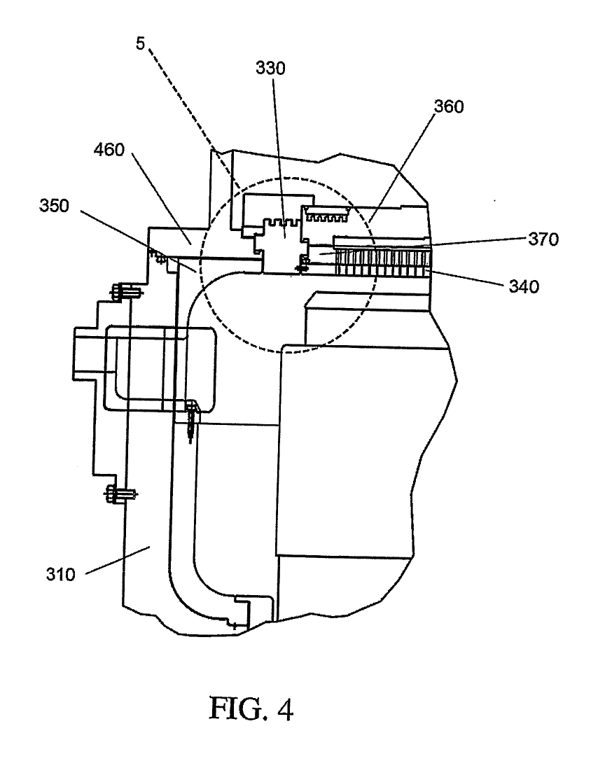

FIGS. 4, 5, 6A and 6B depict a further embodiment of a plasma process chamber 310 utilizing an internal bayonet type interface between a ceramic insulator 330 and an inject plate 340. The plasma process chamber 310 is typically configured such that an upper housing 460 and process chamber liner 350 are electrically insulated from an upper UEL plate 360, a lower UEL plate 370, and the inject plate 340.

Two or more support pins 380 extend from the inject plate 340 outward from the center of the process chamber 310. The support pins 380 are positioned so that they can engage the ceramic insulator 330. A support pin groove 390 in the ceramic insulator 330 is associated with each support pin 380 in the inject plate 340. Each support pin groove 390 has a support pin groove recess 410 which allows reception of a support pin 380. This allows the inject plate 340 to be rotated and locked into the ceramic insulator 330.

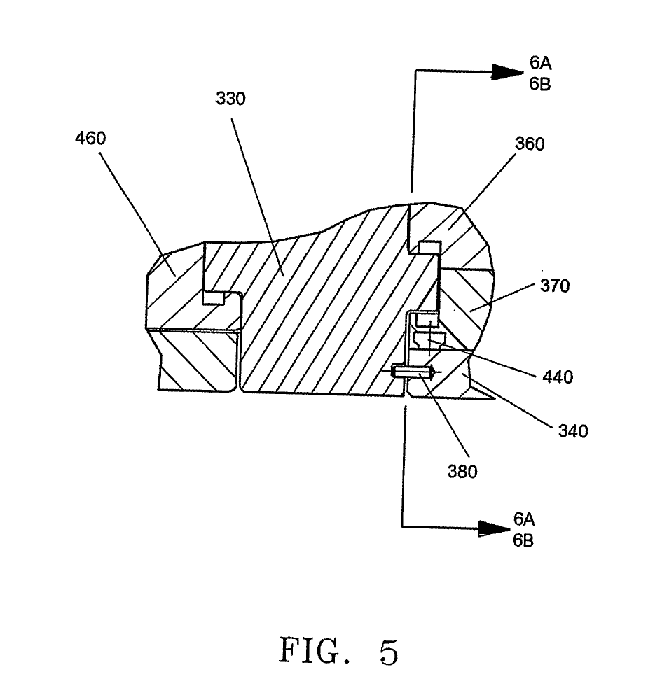

FIG. 6A depicts a possible embodiment of support pin groove 390. The support pins 380 travel along a support pin groove recess 410. The support pin groove 390 has an upper surface 420 and a lower surface 430. The upper surface 420 and the lower surface 430 of support pin groove 390 are approximately parallel to the bottom surface 450 of the ceramic insulator 330.

FIG. 6B depicts a further possible embodiment of support pin grove 390. The upper surface 420 and the lower surface 430 of the support pin groove recess 410 are set an angle beta to the bottom surface 450 of the ceramic insulator 330 which is not zero degrees. This angle beta can allow an axial force between the lower UEL plate 370 and the ceramic insulator 330, as the inject plate 340 is rotated with respect to the ceramic insulator 330.

Other embodiments of groove design are possible. Any types of groove shapes that allow a pin to move along during rotation are possible and are similar to the embodiments shown in FIGS. 6A and 6B.

An electrical contact device 440 can be positioned between the inject plate 340 and the lower UEL plate 370. During rotation of the inject plate 340 the electrical contact device 440 is slightly deformed. This deformation ensures consistent contact between the inject plate 340 and the lower UEL plate 370.

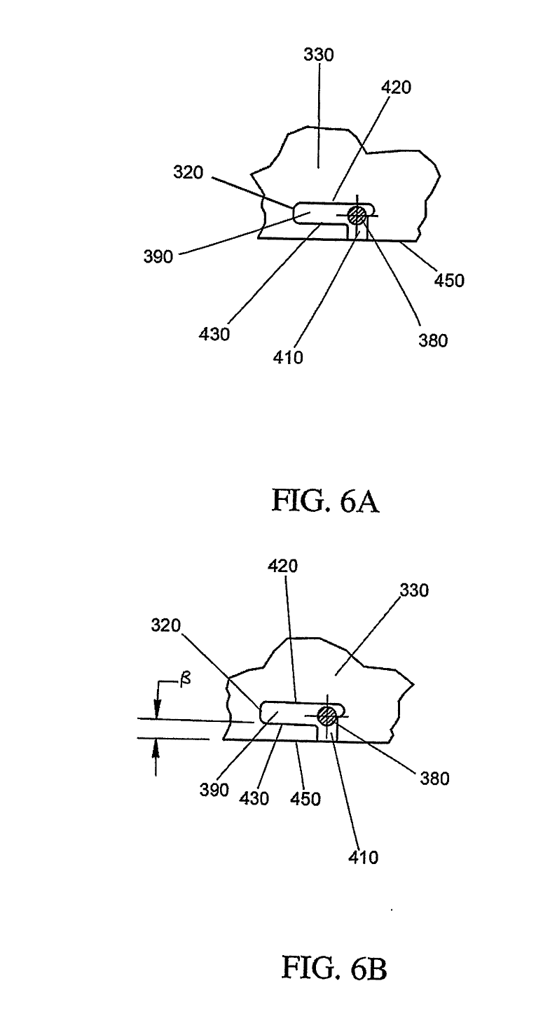

FIGS. 7, 8, and 9 represent yet another embodiment of the present invention wherein two or more threaded fasteners are used to fasten an inject plate 500 to a lower UEL electrode 510.

With reference to FIG. 7, a cross-sectional cut-away view of a plasma processing chamber is depicted. The lower UEL electrode 510 is fastened to an inject plate 500 through the use of a variable height pin 530. The variable height pin 530 can be a threaded fastener or some other type of pin which can be adjusted in height.

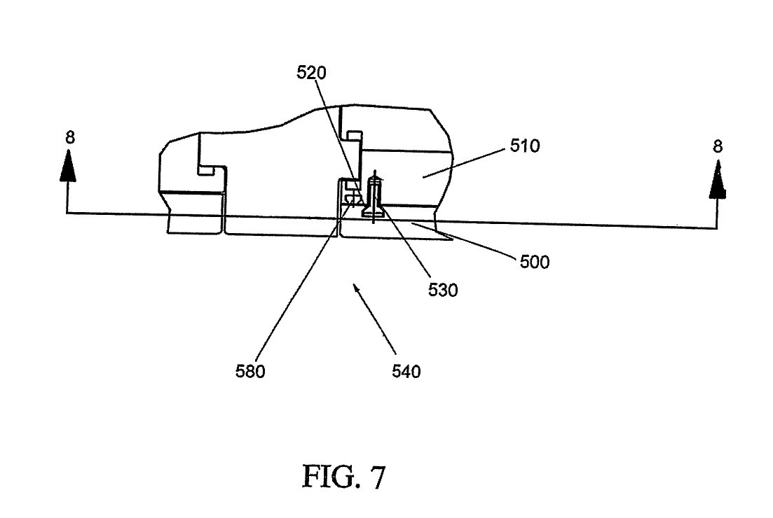

The variable height pin 530 is anchored in the lower UEL plate 510 such that a portion of the pin is left exposed and extending toward the bottom of the process chamber 540. Although not limited thereto, the variable height pin 530 can be any kind of threaded fastener. The depth of the variable height pin 530 can be adjusted precisely by rotation. The exposed portion of the variable height pin 530 has an enlarged portion 520. The enlarged portion 520 of the pin 530 is at least larger in cross-sectional area than the cross-sectional area of the rest of the variable height pin 530. Rotation is accomplished with a slot or similar mating feature located in the inject plate 500 (see FIG. 8). The enlarged portion 520 can be conically shaped.

With reference to FIG. 8, the inject plate 500 possesses at least one mating feature 550 which receives the enlarged portion 520 of variable height pin 530. The mating feature 550 is comprised of a groove counterbore 560 and a retaining groove 570. The groove counterbore 560 is configured such that the diameter thereof is larger than the widest section of the enlarged portion 520. The retaining groove 570 is configured such that the width of the retaining groove 570 is smaller than the widest section of the enlarged portion 520. When the inject plate 500 positioned such that the counterbore 560 is in line with the enlarged portion 520, the enlarged portion 520 is inserted into the counterbore 560 and the inject plate 500 is rotated to captivate the enlarged portion 520, thereby maintaining communication of the inject plate 500 with the lower UEL electrode 510.

An electrical contact device 580 can be present in the lower UEL plate 510. During rotation of the inject plate 500, the electrical contact device 580 is slightly deformed. This deformation ensures consistent contact between the inject plate 500 and the lower UEL electrode 510.

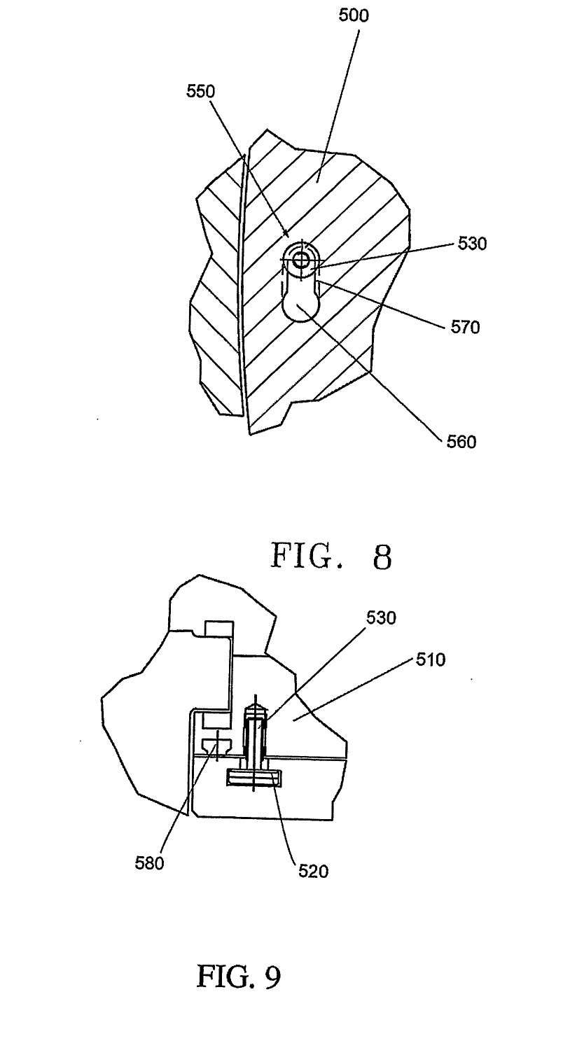

FIG. 9 presents an alternative embodiment wherein the enlarged portion 520 has a rectangular shape rather than a conical shape.

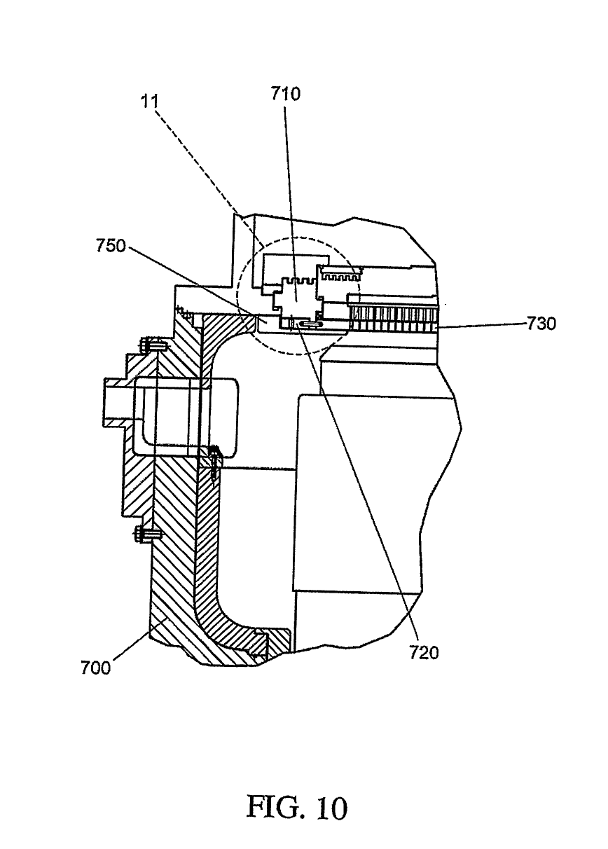

FIGS. 10, 11, and 12 represent a further embodiment of the present invention which utilizes two or more support pins 740 with various shaped support pin retainer assemblies 720 that allow insertion, locking, and removal of the support pins 740 by hand.

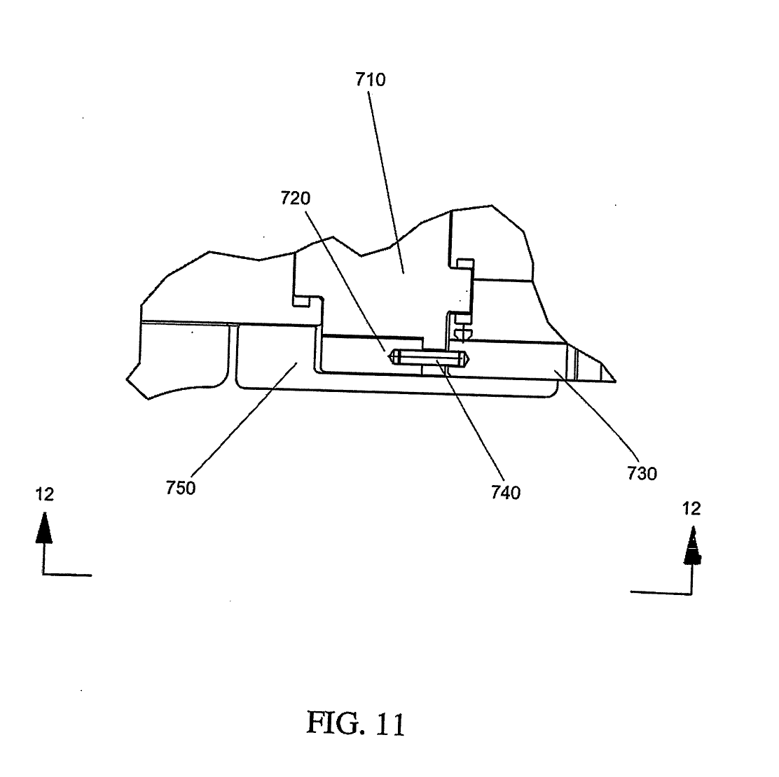

FIG. 10 depicts a cross-sectional view of a process chamber 700. A ceramic insulator 710, located within the process chamber 700, is positioned in communication with a retainer body 720. The retainer body 720 is positioned adjacent an inject assembly 730. A retaining pin 740 is juxtaposed therebetween to ensure communication between the retainer body 720 and the inject assembly 730 is maintained. As can be seen in FIG. 11, the retaining pin 740 extends from the retainer body 720 passing through the ceramic insulator 710 to the inject plate 730. Recess holes (not shown) are provided in both the ceramic insulator 710 and the inject assembly 730 through which the retaining pin 740 can be inserted.

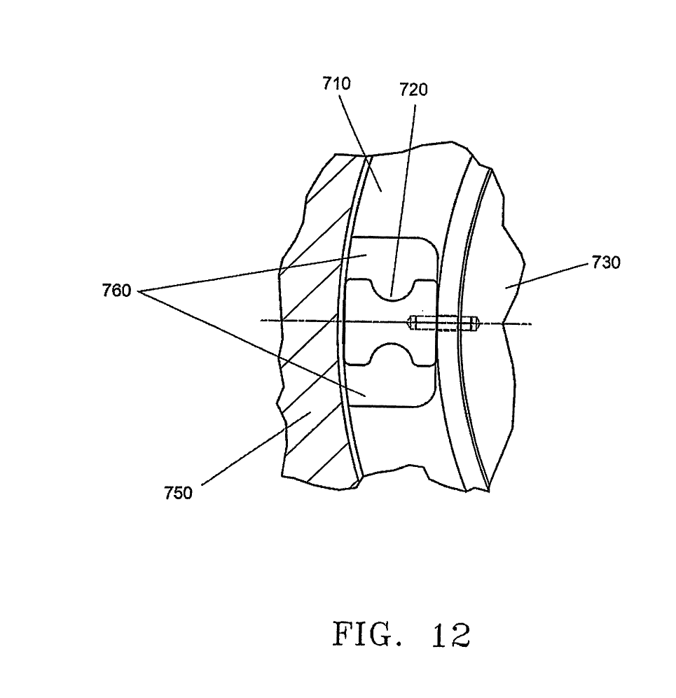

As depicted in FIG. 12, the retainer body 720 is positioned between a shield ring 750 and the inject plate 730. The ceramic insulator 710 has a recess 760. The recess 760 allows for insertion and removal of the retaining pin 740.

Although several embodiments have described the coupling between a ceramic insulator and a shield ring, a ceramic insulator and an inject plate, and an inject plate and an upper electrode, it should be understood that other embodiments are possible as well. For example, the mating/retaining features described herein can be utilized for coupling a first processing component to a second processing component. A processing component can include a focus ring, a shield ring coupled to a lower electrode, a deposition shield, a chamber liner, etc.

1. A plasma processing system comprising:
an inject plate;
a ceramic insulator coupled to the inject plate and including a support pin groove; and
a shield ring for covering a portion of the inject plate and including a support pin embedded therein, the support pin interfacing with the support pin groove to maintain the shield ring in contact with the inject plate.

2. The plasma processing system as claimed in claim 1, wherein the support pin groove is integrated within the ceramic insulator.

3. The plasma processing system as claimed in claim 1, wherein the support pin groove is integrated within the ceramic insulator and substantially parallel to a bottom surface of the ceramic insulator.

4. The plasma processing system as claimed in claim 1, wherein the support pin groove is integrated within the ceramic insulator and extends at an angle toward a top of the ceramic insulator.

5. The plasma processing system as claimed in claim 1, wherein the support pin groove is integrated within the ceramic insulator and extends at an angle toward a bottom of the ceramic insulator.

6. A plasma processing system comprising:
a ceramic insulator coupled to the inject plate and including a support pin groove; and
an inject plate including a support pin embedded therein, the support pin interfacing with the support pin groove to maintain the inject plate in contact with the ceramic insulator.

7. The plasma processing system as claimed in claim 6, wherein the support pin groove is substantially parallel to a bottom surface of the ceramic insulator.

8. The plasma processing system as claimed in claim 6, wherein the support pin groove extends at an angle toward a top of the ceramic insulator.

9. The plasma processing system as claimed in claim 6, wherein the support pin groove extends at an angle toward a bottom of the ceramic insulator.

10. A plasma processing system comprising:
an upper electrode plate including a thread locking device receiving hole;
a thread locking device including a shaft and a hardware attachment opposite the thread locking device receiving hole; and
an inject plate including a mating feature having a groove counterbore and a retaining groove for allowing the hardware attachment to pass through the mating feature via the groove counterbore and retain the inject plate in place via the retaining groove.

11. The plasma processing system as claimed in claim 3 wherein a length of the shaft of the thread locking device protruding from the thread locking device receiving hole is adjustable.

12. A plasma processing system comprising:
a ceramic insulator having a retaining pin receiving hole; and
a retaining pin assembly including a retaining pin for interlocking with the retaining pin receiving hole of the ceramic insulator.
